(19) United States
(12) Patent Application Publication
(10) Pub. No.: US 2014/0378605 A1
(43) Pub. Date: Dec. 25, 2014

(54) Poly[[2,6-4,8-di(5-ethylhexylthienyl)benzo[1,2-b;3,3-b]dithiophene][3-fluoro-2[(2-ethylhexyl)carbonyl]thieno[3,4-b]thiophenediyl]]

(71) Applicant: 1-MATERIAL INC, ST-LAURENT (CA)

(72) Inventors: Shuyong Xiao, St-Laurent (CA); Yali Yang, Point Claire (CA)

(73) Assignee: 1-MATERIAL INC, ST-LAURENT (CA)

(21) Appl. No.: 13/987,006

(22) Filed: Jun. 25, 2013

(51) Int. Cl. H01L 51/00

(52) U.S. Cl. CPC H01L 51/0036
USPC 524/547

(57) ABSTRACT

Preparation and application of poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] as a semiconducting polymer.

### TECHNICAL FIELD

This invention relates to the field of semiconducting polymers and their use in electronic-optical and electronic devices. More particularly, this invention relates to conjugated semiconducting polymers including, Poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]], coded as semiconducting polymer polymer SCP-P in this invention, which are soluble in common organic solvents for fabrication of thin film devices such as organic photovoltaic devices (OPV), organic photo detectors, organic thin film transistors (OTFT) and organic sensors.

### BACKGROUND

Conjugated polymers are organic macromolecules which consist at least of one backbone chain of alternating double- and single-bonds. Due to the fact that the p_{z}-orbitals of the carbon atoms which forms the π-orbitals of the alternating double- and single-bonds mesomerize more or less, i.e. the single and double bonds becomes similar, double-bonds overlaps also over the single bonds, the π-electrons can be easier moved from one bond to the other, what makes conjugated polymers to be a kind of organic semiconductors. In principle one can construct any devices that are available from inorganic semiconductors, like diodes, photo-detectors and transistors, also from these semiconducting polymers.

Semiconducting polymers were initially explored in the application of light emitting diodes, where electricity is covert to visible light. With the recent development of low band gap polymers, there is a rapidly growing interest in using these semiconducting polymers for organic photovoltaic device (OPV or more specifically referred as polymer solar cell, PSC) where sunlight is transformed to electricity. Polymer solar cells being flexible, light weight, inexpensive, colourful, large area devices, portend potential for large scale grip power generation.

In a typical polymer solar cell, the semiconducting polymer acted as a donor material is blended with an acceptor material such as fullerene derivatives, and the blend is sandwiched between a transparency high work function positive electrode (also referred as anode, such as ITO or modified ITO) and a low work function metal negative electrode (also referred as cathode, such as aluminium, modified aluminium). The efficiency of a polymer solar cell, referred as Power Conversion Efficiency (PCE) is proportion to the short circuit current (J_{sc}), the open circuit voltage (V_{oc}) and the filling factor (FF). For a semiconducting polymer to be effectively employed in making a polymer solar cell, the following parameters need to be carefully considered.

First, the semiconducting polymer needs a broad and strong absorption band in visible and near-infrared region to match the solar spectrum for increasing short circuit current (J_{sc}). In term of energy level, this means a smaller band gap (E_{g}), the difference between the Lowest Unoccupied Molecular Orbit (LUMO) and the Highest Occupied Molecular Orbit (HOMO) energy levels.

Secondly, it not only requires the difference between the LUMO and HOMO energy levels to be smaller but also the LUMO and HOMO energy levels themselves to energetically match that of the acceptor in order to facilitate the exciton dissociation at the donor/acceptor interface and to get a higher open circuit voltage (V_{oc}).

Thirdly, the semiconducting polymer needs to have a high charge carrier mobility in order to enhance the charge transport efficiency (to increase J_{sc}) and to increase Filling Factor (FF) of the devices.

Fourthly, the semiconducting polymer needs to have a suitable solubility in common organic solvents in order to make a thin film from its solution.

Fifthly, the semiconducting polymer not only needs be able to form a thin film from its solution but also the formed film needs to be optimal morphology and nano-scaled phase separation of the interpenetrating network of the donor/acceptor blend active layer, which influence the J_{sc}, V_{oc}, and FF of the PSCs significantly.

The above five parameters are each other related. For example, tuning the LUMO and HOMO energy levels will change the energy band-gap so that influences the absorption, improving solubility of the molecules by attaching alkyl side chains will influence their charge carrier mobility and morphology. Therefore, one needs to make a balance among the five parameters to optimize the molecular structure for high photovoltaic performance.

In achieving an optimized balance of these five parameters, many semiconducting polymers have been explored and evaluated. For examples, U.S. Pat. No. 8,304,512 disclosed a family of benzodithiophene based polymers; U.S. Pat. No. 8,367,798 specifically disclosed a family of co-polymers based on 4,8-didodecyloxy-benzo[1,2-b; 3,4-b]dithiophene; U.S. Pat. No. 8,372,945 further disclosed polymer solar cell active layer materials based on conjugated polymers with carbonyl substituted thieno[3,4-b]thiophene units recently.

Despite so many semiconducting polymers have been invented for polymer solar cell active layer materials, the power conversion efficiency (PCE) of solar cells fabricated from these semiconducting polymers is still inferior to that of these solar cells made from inorganic counterparts such as crystalline silicon, mostly due to the fact that the required five parameters from the developed polymer to be used in making a polymer solar cell have not been balanced and optimized in these prior-art semiconducting polymers.

There is a need in the art to develop semiconducting polymers which can balance all the above parameters that ultimately exhibit increased efficiency of semiconducting devices made from the invented polymers.

Furthermore, the reproducibility of the semiconducting polymer is even more important when it is considered to be used in industrial scale to make polymer solar cells. Without a reproducible material, the reported data lose their significance for comparison and validation. Without a reproducible material, the industry loses its potential for scale-up and commercialization.

Therefore, there is another need to develop a reproducible processing in making the developed semiconducting polymers.

### SUMMARY OF THE INVENTION

Accordingly, it is an object of the invention to provide a new composition of matter Poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] and related semiconducting polymers.

It is another object of the invention to provide a process for the synthesis of Poly[[2,6′-4,8-di(5-ethylhexylthienyl)benzo[1,2-b;3,3-b]dithiophene][3-fluoro-2 [(2-ethylhexyl)carbonyl]thieno[3,4-b]thiophenediyl]] and related semiconducting polymers which is reproducible and scalable.

It is another object of the invention to provide shaped articles such as fibers, tapes, films, and the like from solution processing of Poly[[2,6′-4,8-di(5-ethylhexylthienyl)benzo[1,2-b;3,3-b]dithiophene][3-fluoro-2 [(2-ethylhexyl)carbonyl]thieno[3,4-b]thiophenediyl]] and related semiconducting polymers.

It is another object of the invention to provide shaped articles as above described which are electrically semi-conductive.

It is another object of the invention to provide a new composition of matter Poly[[2,6′-4,8-di(5-ethylhexylthienyl)benzo[1,2-b;3,3-b]dithiophene][3-fluoro-2 [(2-ethylhexyl)carbonyl]thieno[3,4-b]thiophenediyl]] and related semiconducting polymers which are readily soluble in a variety of common organic solvents such as chlorinated hydrocarbons and aromatic solvents.

It is another object of the invention to provide a new composition of matter Poly[[2,6′-4,8-di(5-ethylhexylthienyl)benzo[1,2-b;3,3-b]dithiophene][3-fluoro-2 [(2-ethylhexyl)carbonyl]thieno[3,4-b]thiophenediyl]] and related semiconducting polymers which can readily form the desirable thin film from their solutions.

It is another object of the invention to provide a new composition of matter poly[[2,6′-4,8-di(5-ethylhexylthienyl)benzo[1,2-b;3,3-b]dithiophene][3-fluoro-2 [(2-ethylhexyl)carbonyl]thieno[3,4-b]thiophenediyl]] and related semiconducting polymers which exhibit increased solar conversion efficiency when they are used in fabricating organic photovoltaic devices.

### BRIEF DESCRIPTION OF THE DRAWING

FIG. 1 is a graph of the absorption spectrum of the semiconducting polymer prepared as described herein.

FIG. 2 is a graph of the current-voltage characteristics of a device made with a semiconducting polymer prepared as described herein.

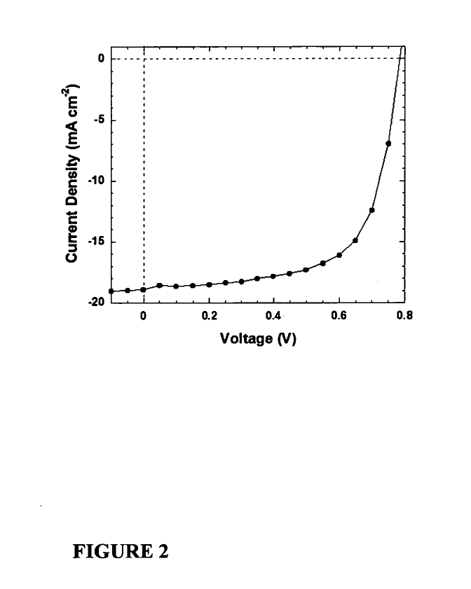

### DETAILED DESCRIPTION OF THE INVENTION

The polymers of the invention poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] and related semiconducting polymers can be described by Formula SCP-I in the following.

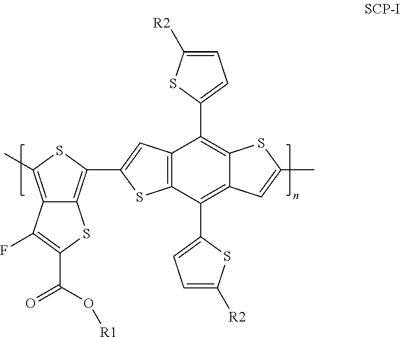

In the above formulation, SCP-I,

R1 is any alkyl group of 1-30 carbons;

R2 is any alkyl group of 1-30 carbons;

n is any number greater than about 10.

Examples of preferred semiconducting polymers (SCP-I) including among others:

R1=propyl, iso-propyl, butyl, iso-butyl, n-hexyl, n-octyl, 2-ethylhexyl, decyl, dodecyl.

R2=propyl, iso-propyl, butyl, iso-butyl, n-hexyl, n-octyl, 2-ethylhexyl, decyl, dodecyl.

The most preferred semiconducting polymer of this invention is R1=ethyl hexyl and R2=ethyl hexyl, which yields a polymer named poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] as described in molecular formulation of SCP-P below:

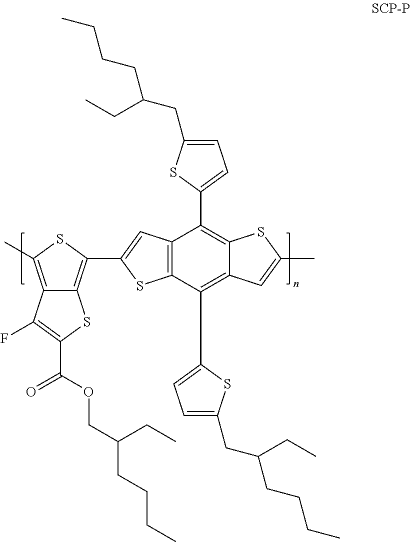

The polymers which are the novel compounds of this invention have a polymeric backbone of benzo[1,2-b;3,3-b]dithiophene and 3-fluoro-thieno[3,4-b]thiophenediyl with specifically designed substituents on both benzo[1,2-b;3,3-b]dithiophene unit and 3-fluoro-thieno[3,4-b]thiophenediyl unit to obtain the desirable properties. The most preferred substituent is ethyl hexyl group on benzo[1,2-b;3,3-b]dithiophene unit and 3-fluoro-thieno[3,4-b]thiophenediyl unit as specifically illustrated in Formula SCP-P.

It is the polymeric backbone of benzo[1,2-b;3,3-b]dithiophene and 3-fluoro-thieno[3,4-b]thiophenediyl which renders the polymer SCP-P shown above a new composition of matter. The alternative connection of benzo[1,2-b;3,3-b]dithiophene unit and 3-fluoro-thieno[3,4-b]thiophenediyl unit defines the optimized LUMO and HOMO energy levels, the energy gap, and the broad and strong absorption band in visible and near-infrared region to match the solar spectrum.

It is also the designed 2-ethylhexyl moieties on both benzo[1,2-b;3,3-b]dithiophene unit and 3-fluoro-thieno[3,4-b]thiophenediyl unit which render the polymer SCP-P shown above a new composition of matter. The designed selection of 2-ethylhexyl moieties on both benzo[1,2-b;3,3-b]dithiophene unit and 3-fluoro-thieno[3,4-b]thiophenediyl unit offers the desirable solubility in common organic solvents in order to make a thin film from its solution and also render the formed film to be optimal morphology, thus yields a higher charge mobility as well.

The balance of electronic property (HOMO and LUMO energy levels), spectroscopic property (absorption) and morphologic property (dense film and nano-scaled phase separation of the interpenetrating network of the donor/acceptor blend active layer) of the invented semiconducting polymer ultimately increases the power conversion efficiency (PCE) of polymer solar cell made from this invented polymer.

The novel semiconducting polymer, poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]], as described in Formula SCP-P can be synthesized by any convenient method know to these skilled in the art. For examples, Scheme-I illustrates a conventional Suzuki Coupling method, Scheme-II illustrates a conventional Direct Heteroaryl Arylation method and Scheme-III illustrates a conventional Stille Coupling method.

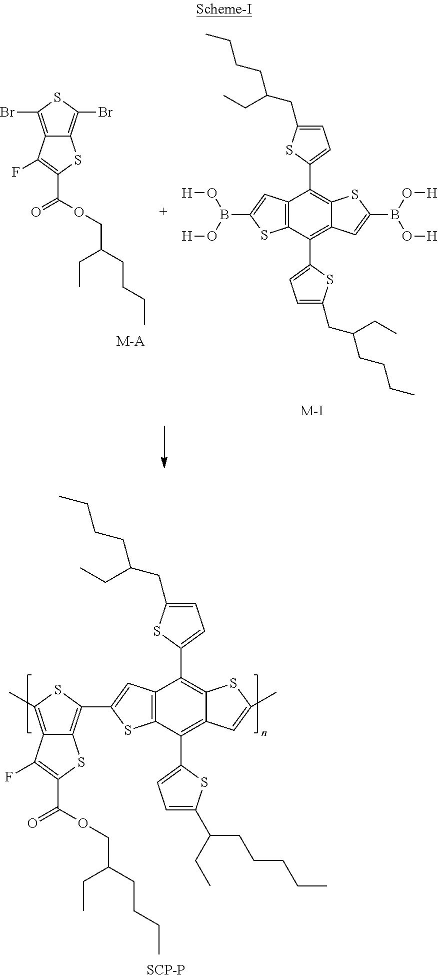

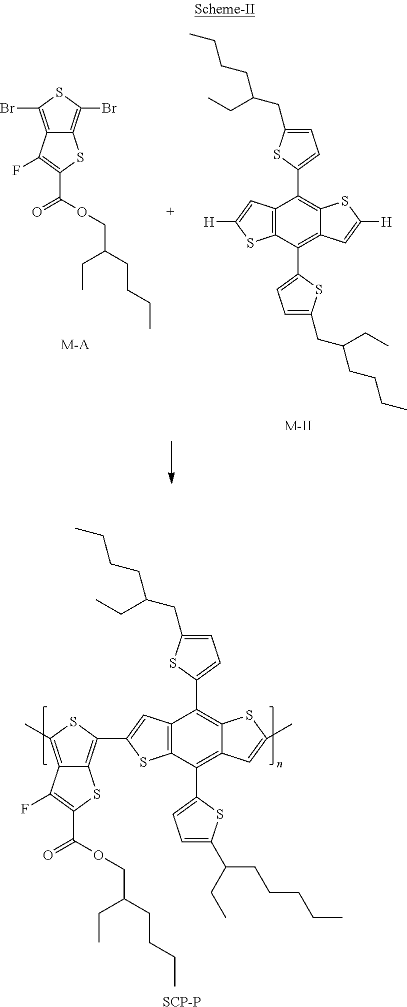

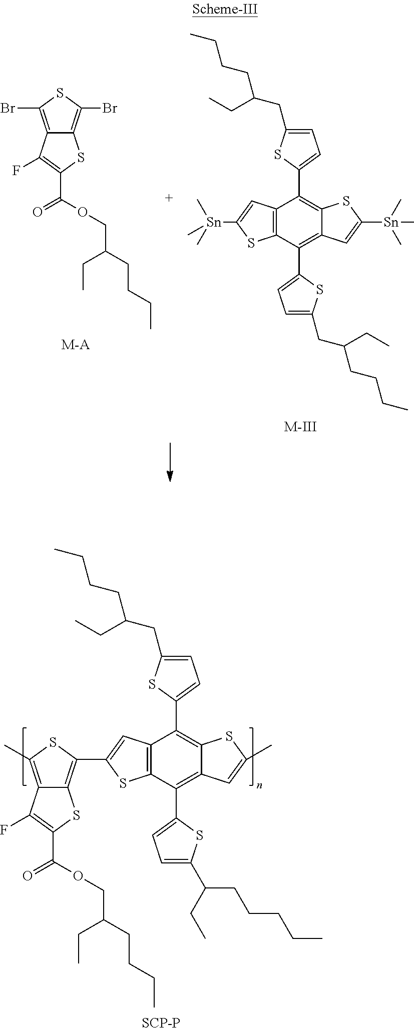

According to this invention, the preferred synthetic approach is Stille Coupling as illustrated in Scheme-III above, which can yield higher molecular weight (larger number of n in Formula SCP-P).

In the example which follows, the specific preparation of poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] by Stille Coupling reaction (Scheme-III) and the application of this semiconducting polymer in making a polymer solar cell are given. It should be understood that the preparation steps are exemplary and are not intended to constitute a limitation of the invention.

### Example 1

### Preparation of poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]]

Poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]] was prepared following Scheme-III. Into a 500 mL flask, 1.03 g (2.18 mmol) of M-A (commercially available from 1-Material Inc, Canada), 1.97 g (2.18 mmol) of M-III (commercially available from 1-Material Inc, Canada), 40 mL of toluene and 40 mL of DMF was charged under argon to give a uniform solution. The obtained solution was bubbled with argon for 30 minutes. Then the solution was added with 50 mg tetrakis(triphenylphosphine) palladium, and stirred at 100° C. for 48 hours. Then the reaction liquid was added with 1 mL of phenylbromide, and further stirred for 5 hours. Then the flask was cooled to room temperature, the reaction liquid was poured into 2000 mL of methanol. The precipitate polymer was collected by filtration. The collected polymer was subjected to soxhlet extraction in a sequence of acetone, hexane, chloroform. The chloroform extraction was concentrated and the concentrated chloroform extraction was poured into acetone to make polymer precipitate. The precipitated polymer was collected again by filtration and dried under vacuum to yield 1.77 g of purified polymer as a shine purplish-black solid.

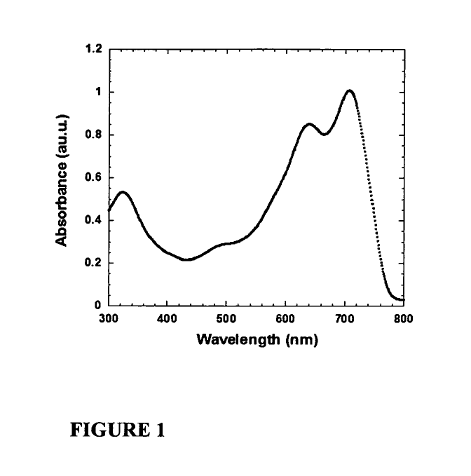

Analysis of this product yielded the following: ¹H NMR (CDCl₃): δ−0.97-1.72 (br), 2.90 (br), 4.25 (br), 6.85-7.40 (br); Cyclic Voltammogram (CV): HOMO=−5.38 eV, LUMO=−3.77 eV, Eg=1.61 eV. GPC (elute in CHCl₃, Polystyrene as standard), Mw=954000, Mn=422000 and PDI=2.26. FIG. 1 presents a graph of absorption spectrum of the obtained polymer, which exhibits a broad absorption band with a peak at about 710 nm.

### Example 2

### Solubility of poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]]

The processing properties were found to be remarkable in that poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]], was found to be fully soluble in common organic solvents. For example, 1% wt/vol (or below) solutions of SCP-P were readily made by dissolving the polymer prepared in EXAMPLE-1 above in chloroform, chlorobenezene, ortho-dichlorobenzene at room temperature or at elevated temperatures.

The SCP-P solutions are dark-purple colored. SCP-P was cast from solution in chlorobenzne and a variety of other solvents onto glass by drop casting or by spin casting to produce shined metallic film of dark purple color. Films were also spin-cat on surface such as quartz, silicon wafer, PET, and ITO (indium-tin oxide coated glass). The films appeared to be both smooth and uniform.

### Example 3

### Application of poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]]

The polymer SCP-P and PC₇₀BM (commercially available from 1-Mateial Inc, Canada) in the weight ratio of 1:1 were co-dissolved in a solvent mixture of 97% (vol/vol) 1,2-dichlorobenzene (DCB) and 3% (vol/vol) 1,8-diiodooctane with a concentrations of 10 mg/ml of polymer and PC₇₀BM respectively.

Indium Tin Oxide (ITO)-coated glass substrates were cleaned stepwise in detergent, water, acetone and isopropyl alcohol under ultrasonication for 15 minutes each and subsequently dried in an oven for 5 hours. A thin layer (˜30 nm) of PEDOT:PSS (Baytron P VP Al 4083) was spin-coated onto ITO surface which was pre-treated by ultraviolet ozone for 15 min. After being baked at 120° C. for ˜20 min, the substrates were transferred into a nitrogen filled glove box. A polymer/PC₇₀BM composites layer (ca.100 nm thick) was then spin-cast from the blend solutions on the ITO/PEDOT:PSS substrate without further special treatments. Then the film was transferred into a thermal evaporator which is located in the same glove box. A Ca layer (25 nm) and an Al layer (80 nm) were deposited in sequence under the vacuum of 2×10⁻⁶ Tor to complete the fabrication of a polymer solar cell. The effective area of film, which was defined the cross section of the patterned ITO (anode) and the deposited metallic layer, was measured to be 0.04 cm².

The fabricated device was encapsulated in nitrogen filled glove box by UV epoxy and cover glass. The current density-voltage (J-V) curves were measured using Keithley 2400 source-measure unit. The photocurrent was measured under AM 1.5 G illumination at 100 mW/cm² under a solar simulator. The light intensity was determined by a mono-silicon detector calibrated by National Renewable Energy Laboratory (NREL). FIG. 1 is a graph of the current-voltage characteristics of a device made with a semiconducting polymer prepared as described herein. From this graph, it was calculated that: Voc (V)=0.79; Jsc (mA/cm²)=18.90; FF (%)=0.64, and to yield an overall PCE (%)=9.56, which is the among the highest PCE reported to date for a single layer polymer solar cell.

Various modifications of the invention are contemplated and can be resorted to by those skilled in the art without departing from the spirit and scope of the invention as defined in the following claims.

### REFERENCE CITED

U.S. PATENT DOCUMENTS

| | | |
|---|---|---|
| 8,304,512 | November 2012 | Wiggleswoth, et al. |
| 8,367,798 | February 2013 | Yang, et al. |
| 8,372,945 | February 2013 | Hou, et al. |

We claim:

1. A semiconducting polymer comprising: poly[[2,6′-4,8-di(5-ethylhexylthienyl)benzo[1,2-b;3,3-b]dithiophene][3-fluoro-2[(2-ethylhexyl)carbonyl]thieno[3,4-b]thiophenediyl]].

2. A film formed from a solvent solution contains the polymer of claim 1.

3. A device made from a film contains the polymer of claim 1.
